(19) United States
(12) Patent Application Publication
(10) Pub. No.: US 2023/0236494 A1
(43) Pub. Date: Jul. 27, 2023

(54) REFLECTIVE HOLOGRAPHIC PHASE MASKS

(71) Applicant: University of Central Florida Research Foundation, Inc., Orlando, FL (US)

(72) Inventors: Ivan Divliansky, Orlando, FL (US); Leonid Glebov, Orlando, FL (US); Lam Mach, Orlando, FL (US); Oussama Mhibik, Oviedo, FL (US)

(21) Appl. No.: 18/101,483

(22) Filed: Jan. 25, 2023

Related U.S. Application Data
(60) Provisional application No. 63/302,735, filed on Jan. 25, 2022.

(51) Int. Cl. G03F 1/26; H01S 3/06; H04B 10/572; G01J 9/02

(52) U.S. Cl. CPC G03F 1/26; H01S 3/0621; H04B 10/572; G01J 9/02; G03H 1/0248

(57) ABSTRACT

A phase transformation device may include a solid photosensitive material having a planar input facet and one or more reflective holographic phase masks (RHPMs) within a volume of the solid photosensitive material, where a particular one of the one or more RHPMs is formed as a periodic refractive index variation of the photosensitive material along a particular grating vector and further with a particular non-planar lateral phase profile, where at least one of a period of the refractive index variation along the grating vector or an orientation of the grating vector for each of the one or more RHPMs are arranged to reflect via Bragg diffraction light incident on the input facet that satisfies a Bragg condition, and where a phase distribution of the reflected light from a particular one of the one or more RHPMs is modified by the associated non-planar lateral phase profile.

### CROSS-REFERENCE TO RELATED APPLICATION

The present application claims the benefit under 35 U.S.C. § 119(e) of U.S. Provisional Application Ser. No. 63/302,735, filed Jan. 25, 2022, entitled REFLECTIVE HOLOGRAPHIC PHASE MASKS FOR PHASE TRANSFORMATION AND MUX/DEMUX OPERATIONS, naming Ivan Divlianski, Leonid Glebov, Lam Mach, and Oussama Mhibik as inventors, which is incorporated herein by reference in the entirety.

### TECHNICAL FIELD

The present disclosure relates generally to holographic phase masks and, more particularly, to reflective holographic phase masks.

### BACKGROUND

The growing adoption of lasers in both research and commercial settings has necessitated the need for coherent sources capable of producing on-demand optical beams with specialized waveforms. Various beam-shaping techniques have been developed to transform the spatial profile of a coherent optical beam from the original distribution to other, more desirable structures, which can be accomplished via either phase or amplitude modulation, or a combination of both. These methods rely on a wide selection of available tools, such as physical apertures, diffractive optical elements, phase masks, free-form optics (e.g., digital micro-mirror devices, or the like), or spatial light modulators. However, these beam-shaping tools, whether active or passive, do not address the underlying monochromatic nature of their embedded phase profiles and are further hampered by the complex, high-cost manufacturing processes as well as a restrictive laser-induced damage threshold. There is therefore a need to develop systems and methods to cure the above deficiencies.

### SUMMARY

A device is disclosed in accordance with one or more illustrative embodiments of the present disclosure. In one illustrative embodiment, the device includes a solid photosensitive material having a planar input facet. In another illustrative embodiment, the device includes one or more reflective holographic phase masks (RHPMs) within a volume of the solid photosensitive material, where a particular one of the one or more RHPMs is formed as a periodic refractive index variation of the solid photosensitive material along a particular grating vector and further with a particular non-planar lateral phase profile in at least one plane perpendicular to the particular grating vector. In another illustrative embodiment, at least one of a period of the refractive index variation along the grating vector or an orientation of the grating vector for each of the one or more RHPMs are arranged to reflect via Bragg diffraction light incident on the input facet that satisfies a Bragg condition. In another illustrative embodiment, a phase distribution of the reflected light from a particular one of the one or more RHPMs is modified by the associated non-planar lateral phase profile.

A system is disclosed in accordance with one or more illustrative embodiments of the present disclosure. In one illustrative embodiment, the system includes a laser source configured to generate a coherent beam of light. In another illustrative embodiment, the system includes an interferometer with a beamsplitter to split the coherent beam into two arms, a phase mask in one of the two arms providing a non-uniform phase distribution in at least one direction perpendicular to a propagation direction of the coherent beam in the associated one of the two arms, and one or more optical elements configured to combine the laser beam from the two arms in a sample to generate interference within the sample, where the interference pattern corresponds to a periodic intensity variation along a grating vector and provides a non-planar lateral phase profile in at least one plane perpendicular to the particular grating vector, and where at least one of a period of the intensity variation along the grating vector or an orientation of the grating vector for each of the one or more RHPMs are arranged to satisfy a Bragg condition associated with the reflection of light incident on the input facet back out of the input facet.

A laser system is disclosed in accordance with one or more illustrative embodiments of the present disclosure. In one illustrative embodiment, the system includes a gain medium to generate optical gain and a cavity surrounding the gain medium configured to generate output laser light based on the optical gain by the gain medium. In another illustrative embodiment, the cavity includes a reflective phase mask including a solid photosensitive material having a planar input facet and one or more reflective holographic phase masks (RHPMs) within a volume of the solid photosensitive material, where a particular one of the one or more RHPMs is formed as a periodic refractive index variation of the solid photosensitive material along a grating vector normal to the input facet and further with a particular non-planar lateral phase profile in at least one plane perpendicular to the grating vector, where a period of the refractive index variation along the grating vector for each of the one or more RHPMs is arranged to retroreflect via Bragg diffraction light of a particular wavelength, where a phase distribution of the reflected light from each of the one or more RHPMs is modified by the associated non-planar lateral phase profile, and where optical modes of the output laser light associated with the wavelengths reflected by the one or more RHPMs are determined by the associated non-planar lateral phase profiles of the associated RHPMs.

A system is disclosed in accordance with one or more illustrative embodiments of the present disclosure. In one illustrative embodiment, the system includes two or more transmitters configured to generate modulated light beams at two or more wavelengths. In another illustrative embodiment, the system includes a multiplexer configured to receive the modulated light beams and direct the modulated beams along a transmission pathway. In another illustrative embodiment, the system includes two or more detectors. In another illustrative embodiment, the system includes a demultiplexer configured to receive the modulated light beams from the transmission pathway and direct the modulated light beams along separate paths to the two or more detectors. In another illustrative embodiment, the system includes one or more phase transformation devices formed as a solid photosensitive material having a planar input facet and two or more reflective holographic phase masks (RHPMs) within a volume of the solid photosensitive material, where a particular one of the two or more RHPMs is formed as a periodic refractive index variation of the solid photosensitive material along a particular grating vector and further with a particular non-planar lateral phase profile in at least one plane perpendicular to the particular grating vector, where at least one of a period of the periodic refractive index variation along the grating vector or an orientation of the grating vector for each of the two or more RHPMs are arranged to reflect via Bragg diffraction light incident on the input facet that satisfies a Bragg condition, and where a phase distribution of the reflected light from a particular one of the one or more RHPMs is modified by the associated non-planar lateral phase profile. In another illustrative embodiment, at least one of the one or more phase transformation devices is configured to operate as at least one of the multiplexer or the demultiplexer.

It is to be understood that both the foregoing general description and the following detailed description are exemplary and explanatory only and are not necessarily restrictive of the invention as claimed. The accompanying drawings, which are incorporated in and constitute a part of the specification, illustrate embodiments of the invention and together with the general description, serve to explain the principles of the invention.

### BRIEF DESCRIPTION OF DRAWINGS

The numerous advantages of the disclosure may be better understood by those skilled in the art by reference to the accompanying figures.

FIG. 1A is a perspective view of the phase transformation device, in accordance with one or more embodiments of the present disclosure.

FIG. 1B is a side view of the phase transformation device along a grating vector associated with a first location in a plane transverse to the grating vector, in accordance with one or more embodiments of the present disclosure.

FIG. 1C is a side view of the phase transformation device along the grating vector with a second location in a plane transverse to the grating vector, in accordance with one or more embodiments of the present disclosure.

FIG. 2 is a series of plots illustrating characteristics of a transmissive volume Bragg grating (VBG), in accordance with one or more embodiments of the present disclosure.

FIG. 3 is a series of plots illustrating characteristics of a reflective VBG, in accordance with one or more embodiments of the present disclosure.

FIG. 4A is a perspective view of a phase transformation device with a single RHPM having a lateral phase distribution characterized as a 1D step function, in accordance with one or more embodiments of the present disclosure.

FIG. 4B is a side view of a phase transformation device with a single RHPM having a lateral phase distribution characterized as a 2D step function, in accordance with one or more embodiments of the present disclosure.

FIG. 4C is an experimental far-field spatial distribution of a reflected beam after interaction with the RHPM depicted in FIG. 4B, in accordance with one or more embodiments of the present disclosure.

FIG. 5 depicts three non-limiting examples of continuous non-planar lateral phase distributions suitable for a RHPM within a phase transformation device, in accordance with one or more embodiments of the present disclosure.

FIG. 6 is a simplified top view of a phase transformation device having three RHPMs with different grating vectors, in accordance with one or more embodiments of the present disclosure.

FIG. 7 is a simplified schematic of an interferometer for fabricating an RHPM, in accordance with one or more embodiments of the present disclosure.

FIG. 8 is a simplified schematic of a phase transformation device with multiple RHPMs formed as a multi-beam Bragg retroreflector, in accordance with one or more embodiments of the present disclosure.

FIG. 9A is a simplified schematic of a phase transformation device with multiple RHPMs formed as an angle-sensitive multiplexer, in accordance with one or more embodiments of the present disclosure.

FIG. 9B is a simplified schematic of a phase transformation device with multiple RHPMs formed as a wavelength-sensitive multiplexer, in accordance with one or more embodiments of the present disclosure.

FIG. 10A is a simplified schematic of a phase transformation device with multiple RHPMs formed as an angle-sensitive demultiplexer, in accordance with one or more embodiments of the present disclosure.

FIG. 10B is a simplified schematic of a phase transformation device with multiple RHPMs formed as a wavelength-sensitive demultiplexer, in accordance with one or more embodiments of the present disclosure.

FIG. 11 is a simplified schematic of a system providing multiplexed communication, in accordance with one or more embodiments of the present disclosure.

FIG. 12 depicts a laser system formed as a gain medium within an optical cavity arranged to generate a coherent output laser beam, in accordance with one or more embodiments of the present disclosure.

### DETAILED DESCRIPTION

Reference will now be made in detail to the subject matter disclosed, which is illustrated in the accompanying drawings. The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure.

Embodiments of the present disclosure are directed to reflective holographic phase masks. Some embodiments of the present disclosure are directed to a reflective holographic phase mask (RHPM) formed as a volume Bragg grating (VBG) within the volume of solid photosensitive material, where the period and/or orientation of the VBG are arranged to provide reflection of incident light via Bragg diffraction, and where a lateral phase profile of the VBG in a plane perpendicular to the grating vector is non-uniform. Put another way, an RHPM as disclosed herein includes a non-planar phase profile of the reflecting VBG in a lateral plane orthogonal to the grating vector.

In this configuration, the non-planar lateral phase profile of the RHPM modifies a phase profile of a beam reflected via Bragg diffraction (e.g., a phase profile in a plane perpendicular to a propagation direction). In a general sense, the RHPM may have any non-planar lateral phase profile such that the RHPM may provide apply any desired phase transformation to a reflected beam.

VBGs are generally described in Igor V. Ciapurin, et al., “Modeling of phase volume diffractive gratings, part 1: transmitting sinusoidal uniform gratings,” Optical Engineering 45 (2006) 015802, 1-9; and Igor V. Ciapurin, et al., “Modeling of phase volume diffractive gratings, part 2: reflecting sinusoidal uniform gratings, Bragg mirrors,” Optical Engineering 51 (2012) 058001, 1-10, both of which are incorporated herein by reference in their entireties. Further, transmissive VBGs (e.g., VBGs for which light satisfying a Bragg condition is diffracted as a transmitted beam) configured as transmissive phase masks are described generally in U.S. Patent Publication No. 2016/0116656 published on Apr. 28, 2016, which is incorporated herein by reference in its entirety.

It is contemplated herein that an RHPM as disclosed herein may have substantially different properties than a transmissive phase mask based on a transmissive VBG. In particular, an RHPM may provide a substantially narrower bandwidth for light redirected via Bragg diffraction than corresponding light diffracted a transmissive VBG, which may make RHPMs particularly useful for, but not limited to, multiplexing and demultiplexing applications, laser applications, and the like.

In some embodiments, two or more RHPMs are fabricated in a common volume of a photosensitive material. Such a configuration may be characterized as a multiplexed RHPM or a multiplexed grating structure. In this configuration, each RHPM may be designed with different characteristics to induce reflection via Bragg diffraction under different conditions such as, but not limited to, different wavelengths, different incidence angles, or different reflection angles. In some embodiments, a phase transformation device with two or more RHPMs is configured as a multiplexer (MUX). For example, the two or more RHPMs may be designed to accept light with different characteristics and redirect them along a common path via reflective Bragg diffraction. In some embodiments, a phase device with two or more RHPMs is configured as a demultiplexer (DEMUX). For example, the two or more RHPMs may be designed to split an incident beam into two or more beams. As an illustration, a wavelength demultiplexer may direct one wavelength of light along one path, a second wavelength of light along a second path, and so on. Further, since each RHPM also includes a non-planar lateral phase profile (which may be the same or different than other multiplexed RHPMs), such a device may further provide individualized phase control of each reflected beam.

Some embodiments of the present disclosure are directed to systems and methods for fabricating an RHPM. In some embodiments, an RHPM is fabricated by placing a solid photosensitive material in an interferometer to generate an interference pattern having the desired characteristics of the RHPM, where one arm of the interferometer includes a phase mask. In this configuration, an interference pattern in the photosensitive material may have the same phase profile as the phase mask in the arm of the interferometer. The light associated with the interference pattern may then induce a material change in the photosensitive material that can be exploited to provide a permanent refractive index variation. An RHPM may be fabricated in any photosensitive material of any type such as, but not limited to, a glass or a polymer. For example, when the photosensitive material is a photo-thermal-refractive (PTR) glass, the light associated with the interference pattern may induce a precipitation of crystalline phases in the glass. A subsequent heat treatment of such a PTR glass (e.g., in an oven) may result in a permanent periodic refractive index variation within the bulk of the glass that corresponds to the desired interference pattern.

It is contemplated herein that it may be necessary to illuminate the solid photosensitive material from opposing facets (or at least multiple facets) to provide interference with a desired orientation in the photosensitive material. For example, it may be desirable to fabricate an RHPM having a grating vector that is substantially perpendicular to a facet of the solid material (e.g., an input facet). In some embodiments, such an arrangement is achieved by placing a solid photosensitive material with two parallel polished facets between two prisms designed to generate an interference pattern between the two facets.

Additional embodiments of the present disclosure are directed to systems or devices that include one or more RHPMs.

For example, some embodiments of the present disclosure are directed to a communications system providing wavelength division multiplexing (WDM). Such a system may include one or more RHPMs as multiplexers to combine modulated light at different wavelengths along a common path for propagation along a communication channel and/or one or more RHPMs as demultiplexers to separate the light from the communication channel along separate paths for separate detection of the modulated light at the different wavelengths.

As another example, some embodiments of the present disclosure are directed to a laser including a phase transformation device with one or more RHPMs within a laser cavity to control a phase of generated laser light (e.g., coherent light) and thus an optical mode of the generated laser light. In particular, the phase transformation device may include one or more RHPMs, each designed to retroreflect light of a selected wavelength within a gain profile of a gain medium and each further designed to provide a non-planar lateral phase profile to control an optical mode of light at the corresponding wavelengths. Such a configuration may support simultaneous generation of laser light with multiple wavelengths and/or multiple optical modes. Further, the bandwidth of the laser light may be controlled by a bandwidth of light reflected by an RHPM via Bragg diffraction, which may be typically be narrow (e.g., on the order of picometers in some cases).

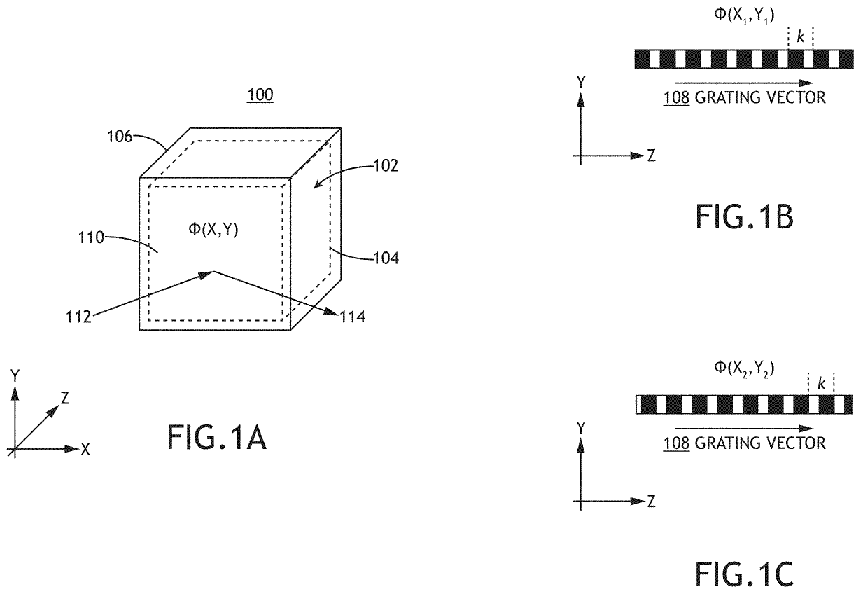

Referring now to FIGS. 1-12, RHPMs are described in greater detail, in accordance with one or more embodiments of the present disclosure.

A traditional VBG is formed as a grating structure associated within the volume of a solid material (e.g., a solid photosensitive material) with a periodic variation of refractive index along a grating vector

$$k = \frac{2 π}{d} .$$

This grating structure is typically extended in directions perpendicular to the grating vector k. The refractive index n of such a traditional VBG may be, but is not required to be, a simple sinusoidal function:

$$n ( x , y , z ) = sin ( \frac{2 π}{d} \cdot z + {ϕ}_{0} ) \qquad ( 1 )$$

where the grating vector k corresponds to z (e.g., a Z axis in an XYZ coordinate space), d is a period of the VBG along the z direction (e.g., the grating vector k), and ϕ₀ corresponds to a constant phase term. In this way, the refractive index of a traditional VBG at the XY plane (or a lateral plane orthogonal to the grating vector more generally) may be constant. Such a traditional VBG may have a uniform phase distribution Φ(x, y)=, where the phase associated with any position in any lateral plane is constant across the VBG. Put another way, such a traditional VBG may be characterized by a planar lateral phase profile.

In embodiments, an RHPM is formed as a VBG with a non-planar lateral phase distribution arranged to reflect light via Bragg diffraction. Using a similar non-limiting construct as above, the refractive index of such an RHPM may be characterized as:

$$n ( x , y , z ) = sin ( \frac{2 π}{d} \cdot z + Φ ( x , y ) ) \qquad ( 2 )$$

where the RHPM may have an arbitrary lateral phase distribution Φ(x, y).

FIGS. 1A-1C depict a phase transformation device 100 formed as an RHPM 102 within a volume 104 of photosensitive material 106, in accordance with one or more embodiments of the present disclosure. In particular, FIGS. 1A-1C depict a non-limiting configuration of a phase transformation device 100 with a single RHPM 102 within a volume 104 of the phase transformation device 100 which has a grating vector 108 oriented along a Z-axis of an XYZ coordinate space. However, it is noted that the grating vector k of a RHPM 102 may generally be oriented in any direction with respect to the input facet 110 so long as a condition for Bragg diffraction is satisfied for at least one wavelength of light incident on the input facet 110 and the associated reflected beam also exits the input facet 110.

FIG. 1A is a perspective view of the phase transformation device 100, in accordance with one or more embodiments of the present disclosure. In particular, FIG. 1A depicts a phase transformation device 100 as a solid block of material (e.g., photosensitive material 106) with an input facet 110 oriented in an XY plane. In this orientation, the refractive index of the RHPM 102 may be described by Equation (2).

FIG. 1B is a side view of the phase transformation device 100 along a grating vector 108 (e.g., Z direction here) associated with a first location in a plane transverse to the grating vector 108 (e.g., X and Y coordinates), in accordance with one or more embodiments of the present disclosure. FIG. 1C is a side view of the phase transformation device 100 along the grating vector 108 with a second location in a plane transverse to the grating vector 108, in accordance with one or more embodiments of the present disclosure. As illustrated in FIGS. 1B and 1C, the phase of the RHPM 102 along the grating vector 108 (e.g., along the Z direction here) associated with different locations of a plane orthogonal to the grating vector 108 (e.g., the XY plane here) may be non-uniform. It is to be understood that although FIGS. 1B and 1C depict the phase as constant over a finite length in the Y direction and as a square wave in the Z direction for illustration, the lateral phase distribution Φ(x, y) may generally be any function supported by the photosensitive material 106.

FIG. 1A further depicts an input beam 112 of light incident on the input facet 110 and a reflected beam 114 of light emanating from the input facet 110 upon reflective Bragg diffraction from a RHPM 102 within the volume 104 of the phase transformation device 100.

As used herein, the term reflected beam 114 is used to describe light that is reflected based on Bragg diffraction by a RHPM 102. For example, a condition for reflective Bragg diffraction may be:

$$sin ( {θ}_{B} ) = \frac{{λ}_{B}}{2 n d} \qquad ( 3 )$$

where d is the period of the RHPM 102 along the grating vector, n is the average refractive index of the processed solid photosensitive material 106 including the RHPM 102, θ_{B} is a Bragg angle (e.g., an incidence angle of the input beam 112 and a corresponding reflection angle of the reflected beam 114 as measured from the grating vector 108), and λ_{B} is the wavelength of diffracted light. It is contemplated herein that the conditions for reflective Bragg diffraction in Equation (3) for a particular RHPM 102 with fixed properties may be satisfied for different combinations of the wavelength λ_{B} and the angle θ_{B}, which allows for tunable operation of the RHPM 102 and the phase transformation device 100 more generally.

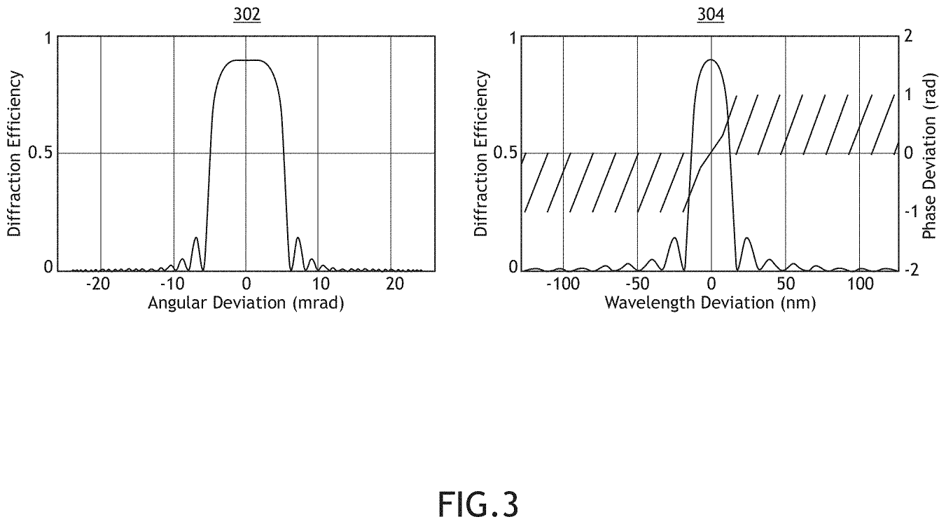

A RHPM 102 may generally be designed to provide reflection via Bragg diffraction (e.g., according to FIG. 3) for at least one wavelength of light incident on the input facet 110, where the reflected beam 114 also exits the same input facet 110. In this configuration, the phase transformation device 100 may operate as a reflective optical element based on the principles of Bragg diffraction.

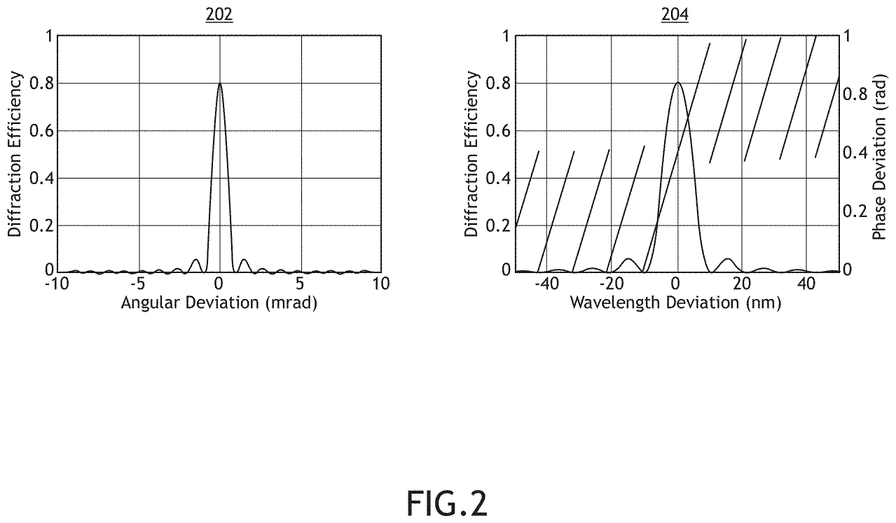

Referring now to FIGS. 2 and 3, characteristics of transmissive and reflective VBGs are described in greater detail.

It is contemplated herein that a reflective VBG (e.g., a RHPM 102 as disclosed herein) may have substantially different properties than a transmissive VBG. For example, the Bragg condition associated with a transmissive VBG may be characterized as:

$$cos ( {θ}_{B} ) = \frac{{λ}_{B}}{2 n d} \qquad ( 4 )$$

using the same variables as defined for Equation (3). As evident by Equations (3) and (4), a transmissive VBG requires a substantially larger Bragg angle θ_{B} for a given grating period d in a given material, which in turn results in substantially different spectroscopic properties for transmissive and reflective VBGs.

FIGS. 2 and 3 represent characteristics of transmissive and reflective VBGs with different associated periods designed to provide Bragg reflection for a common wavelength λ_{B} and Bragg angle θ_{B} for comparative purposes.

FIG. 2 is a series of plots illustrating characteristics of a transmissive VBG, in accordance with one or more embodiments of the present disclosure. In particular, plot 202 depicts diffraction efficiency as a function of angular deviation for a particular wavelength, and plot 204 depicts the diffraction efficiency and phase deviation as a function of wavelength.

FIG. 3 is a series of plots illustrating characteristics of a reflective VBG (e.g., a RHPM 102), in accordance with one or more embodiments of the present disclosure. In particular, plot 302 depicts diffraction efficiency as a function of angular deviation for a particular wavelength, and plot 304 depicts the diffraction efficiency and phase deviation as a function of wavelength.

Comparing FIGS. 2 and 3, the reflective VBG (e.g., as described by FIG. 3) exhibits substantially narrower selectivity for Bragg diffraction than a comparable transmissive VBG. For instance, the bandwidths of diffracted light by a reflective VBG as a function of both wavelength and angle are substantially narrower than corresponding bandwidths of diffracted light by a transmissive VBG. As a result, a reflective VBG (e.g., a RHPM 102 as disclosed herein) may generally be well-suited, for narrow bandwidth applications such as, but not limited to, wavelength multiplexing/demultiplexing, wavelength/phase control within a laser cavity, or the like.

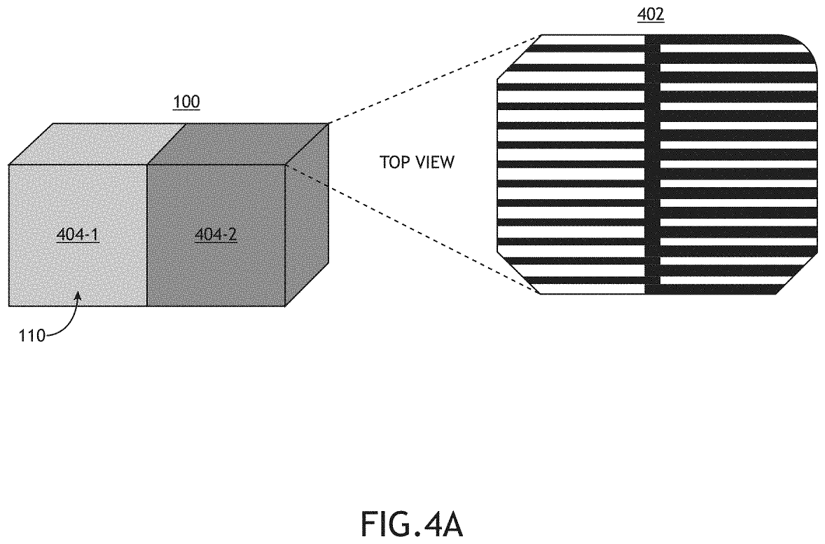

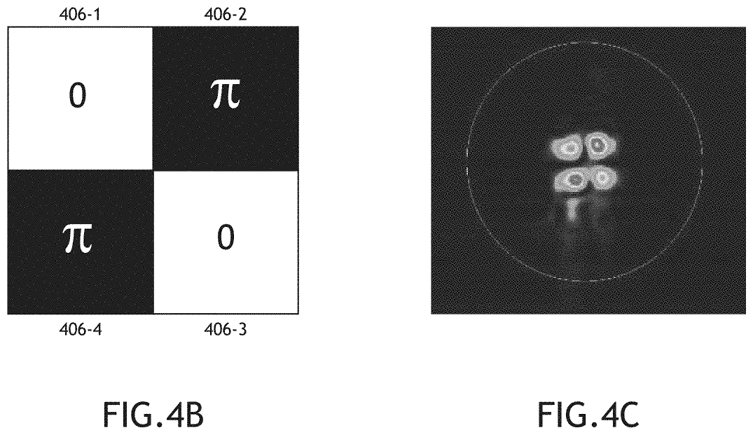

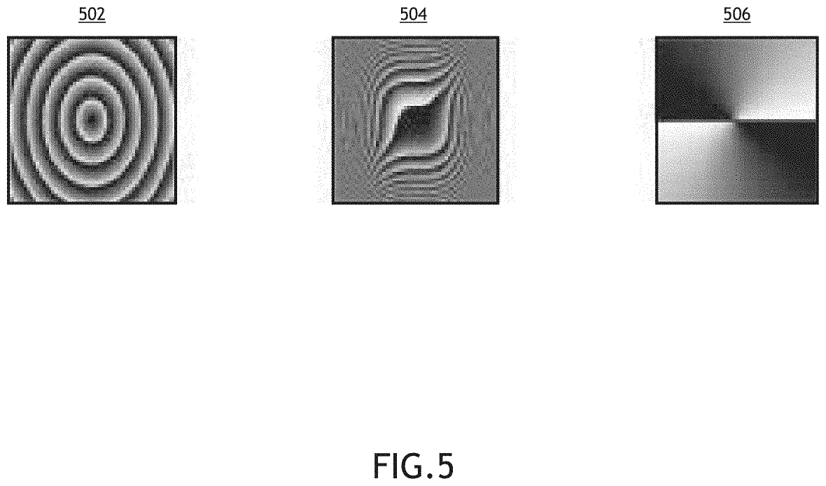

Referring now to FIGS. 4A-5C, various non-limiting examples of RHPMs 102 with non-planar lateral phase distributions are illustrated, in accordance with one or more embodiments of the present disclosure.

In some embodiments, a RHPM 102 includes two or more regions, where the lateral phase distribution is uniform within each region, but different regions may have different phases. The lateral phase distribution Φ(x, y) of such a RHPM 102 may be characterized as a step function along one or more directions.

FIG. 4A is a perspective view of a phase transformation device 100 with a single RHPM 102 having a lateral phase distribution Φ(x, y) characterized as a 1D step function, in accordance with one or more embodiments of the present disclosure. Inset 402 depicts a top view of the phase transformation device 100. In particular, FIG. 4A illustrates a non-limiting configuration of a phase transformation device 100 with a single RHPM 102 having a binary lateral phase distribution. For example, the RHPM 102 in FIG. 4A includes a first region 404-1 and a second region 404-2 with phases that differ by π. For instance, the phase of the first region 404-1 may be characterized as Φ=0 and the phase of the second region 404-2 may be characterized as Φ=π.

FIG. 4B is a side view of a phase transformation device 100 with a single RHPM 102 having a lateral phase distribution Φ(x, y) characterized as a 2D step function, in accordance with one or more embodiments of the present disclosure. In particular, FIG. 4B depicts a RHPM 102 with lateral phase distribution Φ(x, y) providing four regions (e.g., quadrants), where one set of opposing quadrants (e.g., 406-1 and 406-3) have a relative phase of 0 (Φ=0) and a second set of opposing quadrants (e.g., 406-2 and 406-4) have a relative phase of π (Φ=π). FIG. 4C is an experimental far-field spatial distribution of a reflected beam 114 after interaction with the RHPM 102 depicted in FIG. 4B, in accordance with one or more embodiments of the present disclosure. In particular, FIG. 4C depicts mode conversion of a Gaussian input beam 112 to a beam with a transverse electromagnetic mode (TEM) 11 profile in the far field.

It is noted that although FIGS. 4A-4C depict square regions, a RHPM 102 may generally have any number of regions of constant phase, where the various regions have any shapes and distributions, and where each of the various regions may have an arbitrary phase value.

In some embodiments, a RHPM 102 includes a non-uniform lateral phase profile characterized by a continuous function along one or more directions.

FIG. 5 depicts three non-limiting examples 502, 504, 506 of continuous non-planar lateral phase distributions suitable for a RHPM 102 within a phase transformation device 100, in accordance with one or more embodiments of the present disclosure.

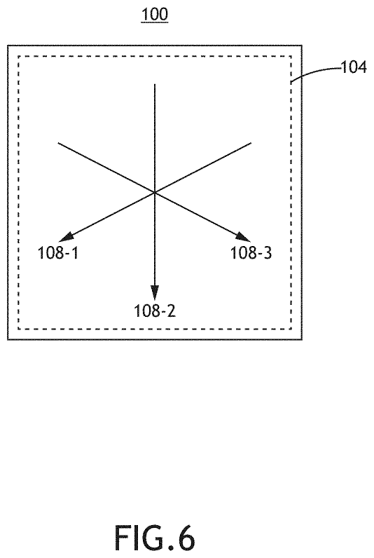

Referring now to FIG. 6, a phase transformation device 100 may generally include any number of RHPMs 102 within a common volume 104 of photosensitive material 106. Further, each RHPM 102 may have any selected orientation of a grating vector 108 as well as any selected lateral phase distribution (e.g., phase distribution Φ in a lateral plane orthogonal to the associated grating vector). In this way, the refractive index distribution in the volume 104 of the phase transformation device 100 may be a complex function with periodicity in multiple directions associated with multiple grating vectors. A phase transformation device 100 with multiple RHPMs 102 with multiple grating vectors 108 may be well suited for, but not limited to, applications involving multiplexing and/or demultiplexing of light.

FIG. 6 is a simplified top view of a phase transformation device 100 having three RHPMs 102 with different grating vectors (labeled as 108-1, 108-2, and 108-3), in accordance with one or more embodiments of the present disclosure. For clarity of illustration, the RHPMs 102 are depicted in FIG. 6 by the associated grating vectors 108-1, 108-2, and 108-3 rather than varying refractive index profiles.

Referring generally to FIGS. 1A-6, it is recognized herein that an RHPM 102 may provide highly-selective operation to selectively reflect light that satisfied a Bragg condition regardless of the spectrum of the associated input beam 112. For example, in the case that a spectrum of the input beam 112 is broader than an operational bandwidth of a particular RHPM 102, the RHPM 102 may selectively reflect only the narrow bandwidth satisfying the Bragg condition and transmit the remaining wavelengths.

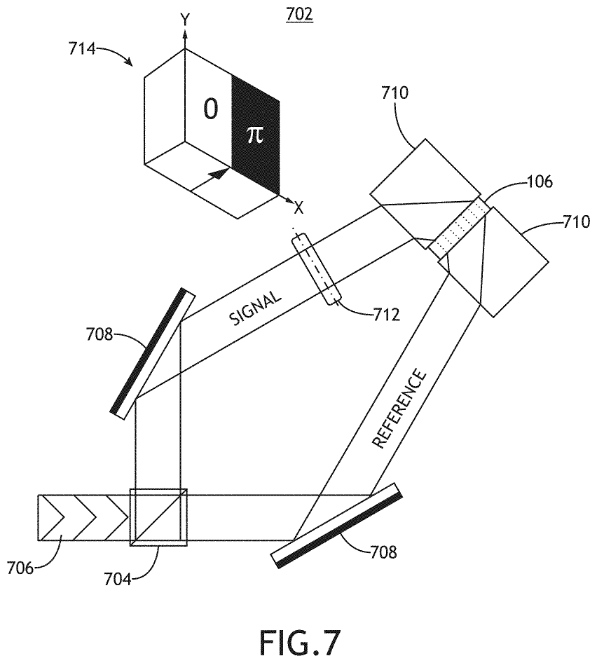

Referring now to FIG. 7, fabrication of an RHPM 102 is described in greater detail. FIG. 7 is a simplified schematic of an interferometer 702 for fabricating an RHPM 102, in accordance with one or more embodiments of the present disclosure.

In some embodiments, an RHPM 102 is formed by placing a photosensitive material 106 in an interferometer 702 such that an interference pattern associated with a desired reflective VBG is formed in the photosensitive material 106. In this way, one or more properties of the photosensitive material 106 may change in response to the incident illumination such that the interference pattern is exposed in the photosensitive material 106. As necessary, additional steps such as, but not limited to, heating the photosensitive material 106 may be performed to render the exposed interference pattern more permanent.

The photosensitive material 106 may include any photosensitive material known in the art suitable for supporting a phase transformation device 100. For example, the photosensitive material 106 may include a photosensitive glass, a photosensitive polymer, or the like.

In some embodiments, the photosensitive material 106 includes PTR glass. For example, PTR glass may include one or more photosensitive dopants and/or one or more halogen ions. As an illustration PTR glass may include, but is not limited to, sodium aluminosilicate glass containing sodium fluoride (NaF) and potassium bromide (KBr) along with silver, cerium, tin, and/or antimony oxides. Such a material may produce various photoionized states upon exposure with ultraviolet (UV) light (typically including silver) that may further crystallize into nucleation centers (e.g., nanoclusters, crystalline phases, or the like) upon thermal treatment (e.g., heating and/or cooling). Any suitable device may be used to provide the heat treatment including, but not limited to, an oven. Further, species such as NaF, NaBr, or the like may be formed during the thermal treatment. The resulting exposed interference pattern may be patterned into the volume of the photosensitive material 106. However, it is recognized herein that various compositions of PTR glass may be developed and that the present disclosure is not limited to any particular composition or any particular thermal treatment profile.

In some embodiments, an RHPM 102 is formed in a photosensitive material 106 directly as a result of exposure with light without the need for thermal treatment.

In some embodiments, the interferometer 702 includes a beamsplitter 704 (e.g., a non-polarizing beamsplitter) to split incident light 706 suitable for exposing the desired interference pattern in the photosensitive material 106 into two paths associated with arms of the interferometer 702 (e.g., signal and reference arms). The light 706 may have any spectral properties and intensity suitable for exposing the interference pattern in the photosensitive material 106. For example, in the case of PTR glass, the light 706 may include UV illumination (e.g., 325 nm, or the like).

In some embodiments, the interferometer 702 further includes various optical elements (e.g., mirrors 708, or the like) to direct the light 706 in the two arms of the interferometer 702 to the photosensitive material 106 at angles necessary to produce a desired interference pattern associated with an RHPM 102 as disclosed herein. For example, as depicted in FIG. 7, a photosensitive material 106 having parallel polished faces may be placed between a pair of prisms 710 or other suitable elements (e.g., mirrors, or the like) to direct light through the parallel facets and generate an interference pattern with a grating vector that is substantially perpendicular to the polished facets. In this configuration, one of the polished facets of the photosensitive material 106 may operate as the input facet 110 as illustrated in FIG. 1A. Further, the orientation of the grating vector k and/or the grating period d may be tuned or otherwise controlled based on the geometry of the prisms 710 (or other mirrors, or the like) and/or the angles at which the light 706 is directed into each of the facets. As an illustration, illumination of a photosensitive material 106 using the interferometer 702 depicted in FIG. 7 with light 706 having a wavelength of 325 nm at a recording angle of θ_{rec} may result in Bragg diffraction of such light at an angle of −θ_{Rec}. In some embodiments, one or more components of the interferometer 702 (e.g., the prisms 710, mirrors 708, or the like) are adjustable to allow adjustments of the grating vector k and/or the grating period d associated with the interference pattern. For example, one or more components of the interferometer 702 may be mounted on translation stages (e.g., rotational stages, linear stages, or the like) suitable for adjusting the associated angles and/or positions.

In some embodiments, the interferometer 702 further includes a phase plate 712 located in one arm of the interferometer 702 (e.g., the signal arm as illustrated in FIG. 7). In this configuration, a phase plate 712 may modify the phase distribution of the RHPM 102 such that the RHPM 102 has a non-planar lateral phase profile Φ. Inset 714 further depicts a perspective view of the phase plate 712 with a non-limiting configuration of a binary transmissive phase profile.

It is contemplated herein that a reflected beam 114 associated with Bragg diffraction from an RHPM 102 fabricated with an interferometer 702 as depicted in FIG. 7 may have a phase profile that matches or is controlled by (e.g., depends on) the phase profile of the phase plate 712. Further, this is true for any wavelength of light reflected via Bragg diffraction by the RHPM 102 (e.g., any wavelength for which the Bragg diffraction condition in Equation (3) is satisfied and for which the arrangement of the RHPM 102 and the input beam 112 allow for the reflected beam 114 to exit the input facet 110 as described above).

In this way, the phase profile induced on a reflected beam 114 from the RHPM 102 may be controlled by selection of the phase profile of the phase plate 712 used during fabrication of the RHPM 102.

In some embodiments, multiple RHPMs 102 are fabricated in a single piece of photosensitive material 106 through successive exposures to interference patterns by the interferometer 702. For instance, various components of the interferometer 702 (e.g., the prisms 710, mirrors 708, or the like) may be modified for each exposure to provide a selected grating vector 108 and/or period for each RHPM 102. In the case of a photosensitive material 106 including PTR glass or other material benefiting from a thermal treatment to generate a permanent refractive index change in the pattern of the exposed interference pattern, such a thermal treatment may be performed after all exposures or between exposures as desired for the selected composition.

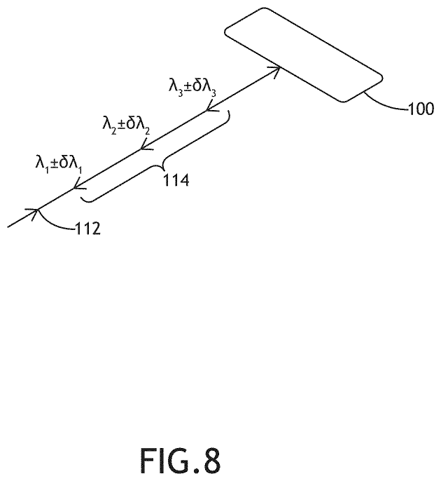

Referring now to FIGS. 8-12, various non-limiting systems and devices incorporating at least one RHPM 102 are described in greater detail, in accordance with one or more embodiments of the present disclosure.

In some embodiments, two or more RHPMs 102 are formed in a photosensitive material 106 (e.g., within a common volume 104 of the photosensitive material 106) as a phase transformation device 100, where each RHPM 102 is designed to provide Bragg diffraction of a selected wavelength of light with a specified reflection angle relative to the input facet 110, and where each RHPM 102 has a different non-planar lateral phase profile Φ. For example, properties of each RHPM 102 such as, but not limited to, the period d, the orientation of the grating vector 108 relative to the input facet 110, and/or the non-planar lateral phase profile Φ may be independently selected. In this configuration, the phase transformation device 100 may simultaneously operate as a reflective phase mask with defined reflection angles for multiple beams of light.

Referring to FIG. 8, FIG. 8 is a simplified schematic of a phase transformation device 100 with multiple RHPMs 102 formed as a multi-beam Bragg retroreflector, in accordance with one or more embodiments of the present disclosure. For example, two or more RHPMs 102 may be formed with grating vectors 108 oriented normal to the input facet 110 and periods d selected to provide reflection via Bragg diffraction of a selected wavelength of light. Further, each of these RHPMs 102 may have a selected non-planar lateral phase profile Φ.

For example, as depicted in FIG. 8, such a phase transformation device 100 may be configured as a multi-wavelength retroreflector. In this configuration, each RHPM 102 may be designed to reflect a different wavelength of light via Bragg diffraction. FIG. 8 depicts a non-limiting example of simultaneous retroreflection of three beams with different center wavelengths and/or bandwidths, represented as λ₁±δλ₁, λ₂±δλ₂, and λ₃±δλ₃. As illustrated in FIG. 3, an RHPM 102 may generally provide highly selective narrowband reflection around a center wavelength for a given incidence angle. In particular, an RHPM 102 may provide more highly selective reflection of a smaller bandwidth around a center wavelength than a corresponding transmissive VBG.

Further, such a multi-wavelength retroreflector may provide selective control of the phase of each reflected beam 114 (retroreflected light at each center wavelength). In some embodiments, all of the RHPMs 102 have the same non-planar lateral phase profile Φ. In some embodiments, at least some RHPMs 102 have different non-planar lateral phase profiles to impart different phase transformations on different reflected beams 114 at different wavelengths. As non-limiting illustrations, any of the RHPMs 102 may have any of the non-planar lateral phase profiles illustrated in FIG. 5.

In some embodiments, a phase transformation device 100 includes two or more RHPMs 102 arranged to provide multiplexing of two or more beams. For example, multiple input beams 112 with different angles of incidence (e.g., incidence angles) on the input facet 110 may be reflected via Bragg diffraction to a common reflection angle relative to the input facet 110. In this configuration, each RHPM 102 may have a grating vector 108 and/or period selected to provide reflection via Bragg diffraction of a selected wavelength of light to the common reflection angle. Further, each RHPM 102 may have any selected non-planar lateral phase profile to impart any selected phase distribution on the associated reflected beam 114.

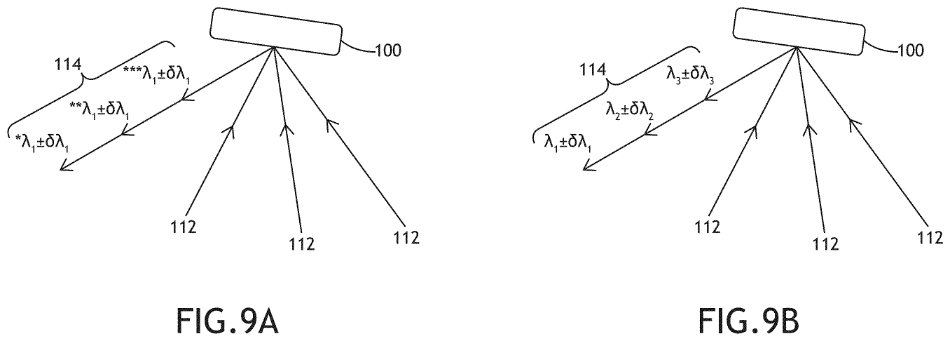

FIG. 9A is a simplified schematic of a phase transformation device 100 with multiple RHPMs 102 formed as an angle-sensitive multiplexer, in accordance with one or more embodiments of the present disclosure. In this configuration, the grating vector 108 and/or period of each RHPM 102 is selected to reflect a common wavelength with different Bragg angles in a way that all associated reflected beams 114 overlap with a common reflection angle relative to the input facet 110. This is represented in FIG. 9A by overlapping reflected beams 114 with spectral profiles of λ₁*±δλ₁, λ₁**±δλ₁, and λ₁***±δλ₁. The associated RHPMs 102 in this configuration may have the same or different non-planar lateral phase profiles to provide independent control of the phase of each reflected beam 114.

FIG. 9B is a simplified schematic of a phase transformation device 100 with multiple RHPMs 102 formed as a wavelength-sensitive multiplexer, in accordance with one or more embodiments of the present disclosure. In this configuration, the grating vector 108 and/or period of each RHPM 102 is selected to reflect different wavelengths with different Bragg angles in a way that all associated reflected beams 114 overlap with a common reflection angle relative to the input facet 110. Further, the RHPMs 102 may have the same or different non-planar lateral phase profiles to provide independent control of the phase of each reflected beam 114. This is represented in FIG. 9B by overlapping reflected beams 114 with spectral profiles of λ₁±δλ₁, λ₂±δλ₂, and λ₃±δλ₃. The associated RHPMs 102 in this configuration may have the same or different non-planar lateral phase profiles to provide independent control of the phase of each reflected beam 114.

In some embodiments, a phase transformation device 100 includes two or more RHPMs 102 arranged to provide demultiplexing of two or more beams. For example, multiple input beams 112 with common incidence angles on the input facet 110 may be reflected via Bragg diffraction to different reflection angles relative to the input facet 110. In this configuration, each RHPM 102 may have a grating vector 108 and/or period selected to provide reflection via Bragg diffraction of a selected wavelength of light at the common incidence angle to selected reflection angles. Further, each RHPM 102 may have any selected non-planar lateral phase profile to impart any selected phase distribution on the associated reflected beam 114.

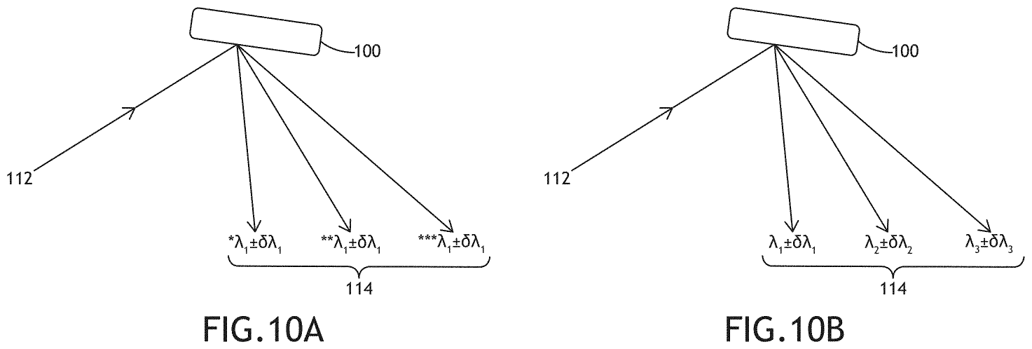

FIG. 10A is a simplified schematic of a phase transformation device 100 with multiple RHPMs 102 formed as an angle-sensitive demultiplexer, in accordance with one or more embodiments of the present disclosure. In this configuration, the grating vector 108 and/or period of each RHPM 102 is selected to reflect a common wavelength with different Bragg angles in a way that the associated reflected beams 114 have different reflection angles relative to the input facet 110. This is represented in FIG. 10A by non-overlapping reflected beams 114 with spectral profiles of λ₁*±δλ₁, λ₁**±δλ₁, and λ₁***±δλ₁. The associated RHPMs 102 in this configuration may have the same or different non-planar lateral phase profiles to provide independent control of the phase of each reflected beam 114.

FIG. 10B is a simplified schematic of a phase transformation device 100 with multiple RHPMs 102 formed as a wavelength-sensitive demultiplexer, in accordance with one or more embodiments of the present disclosure. In this configuration, the grating vector 108 and/or period of each RHPM 102 is selected to reflect different wavelengths with different Bragg angles in a way that the associated reflected beams 114 have different reflection angles relative to the input facet 110. This is represented in FIG. 10B by non-overlapping reflected beams 114 with spectral profiles of λ₁±δλ₁, λ₂±δλ₂, and λ₃±δλ₃. The associated RHPMs 102 in this configuration may have the same or different non-planar lateral phase profiles to provide independent control of the phase of each reflected beam 114.

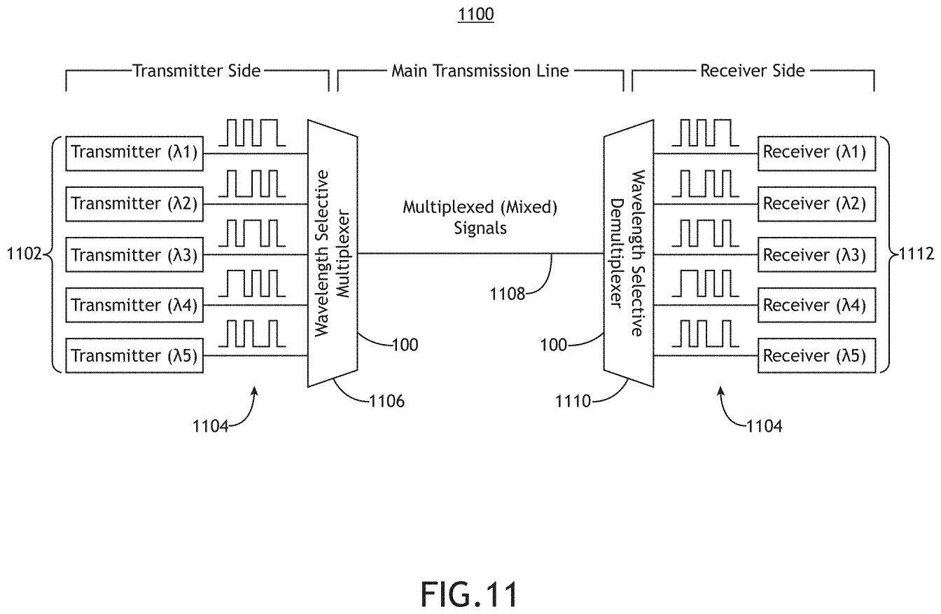

Referring now to FIG. 11, FIG. 11 is a simplified schematic of a system 1100 providing multiplexed communication, in accordance with one or more embodiments of the present disclosure. In some embodiments, a system 1100 includes two or more transmitters 1102 configured to generate modulated beams 1104 having different wavelengths (e.g., center wavelengths) and one or more wavelength-selective multiplexers 1106 to combine the modulated beams 1104 to a common optical path for transmission over a transmission line 1108 (e.g., a free-space transmission line, a fiber-optic cable, or a network thereof). In some embodiments, the system 1100 further includes one or more wavelength-selective demultiplexers 1110 to receive the light from the transmission line 1108 (e.g., along a common optical path) and split the modulated beams 1104 into different optical paths for separate detection by different receivers 1112 (e.g., photodiodes, avalanche photodiodes, single photon detectors, or the like).

It is contemplated herein that a phase transformation device 100 with two or more RHPMs 102 may operate as any of the multiplexers 1106 and/or the demultiplexers 1110. For example, any of the multiplexers 1106 may be implemented as illustrated in FIG. 9B. As another example, any of the demultiplexers 1110 may be implemented as illustrated in FIG. 10B. Further, in this configuration, any such phase transformation device 100 may selectively control the phase of each associated modulated beam 1104 as disclosed herein. In this way, the phase profiles of the modulated beams 1104 may be tailored as desired for efficient operation of the system 1100.

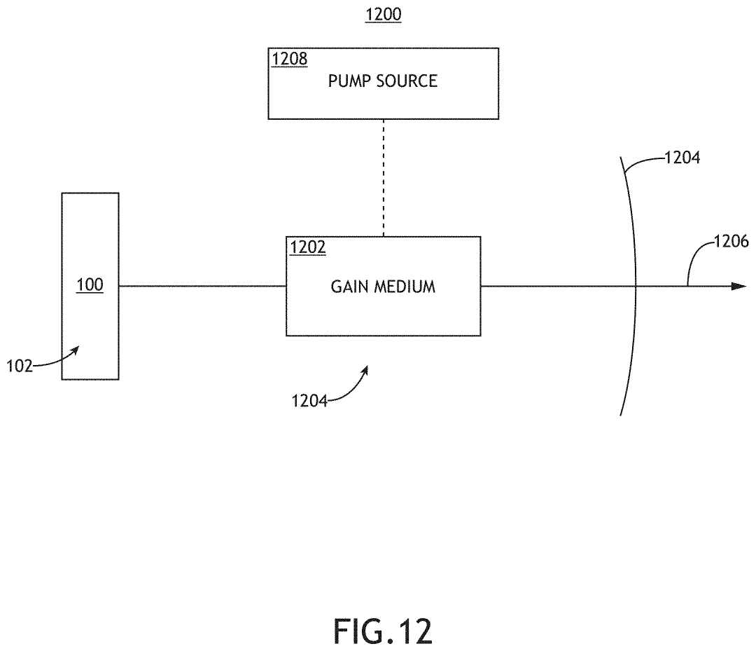

Referring now to FIG. 12, in some embodiments, a laser system 1200 includes an intracavity phase transformation device 100 with one or more RHPMs 102 to provide highly selective wavelength and mode control laser output, in accordance with one or more embodiments of the present disclosure.

As a non-limiting illustration, FIG. 12 depicts a laser system 1200 formed as a gain medium 1202 within an optical cavity 1204 arranged to generate a coherent output laser beam 1206, in accordance with one or more embodiments of the present disclosure. The gain medium 1202 may be pumped by any suitable pump source 1208. For example, the pump source 1208 may include an optical pump source to provide pump light within an absorption band of the gain medium 1202. As another example, the pump source 1208 may be an electrical pump source configured to provide electrical pumping of the gain medium 1202.

In some embodiments, the laser system 1200 includes a phase transformation device 100 with one or more RHPMs 102 within the optical cavity 1204. For example, as illustrated in FIG. 12, the phase transformation device 100 may operate as a mirror within the optical cavity 1204.

The phase transformation device 100 may have any design suitable for operation in the laser system 1200. For example, any RHPMs 102 of the phase transformation device 100 may be oriented with a grating vector 108 normal to an input facet 110 to provide retroreflecting operation.

It is contemplated herein that an RHPM 102 within an optical cavity 1204 of a laser system 1200 may selectively allow lasing of a narrow bandwidth of light that satisfies the Bragg condition and may further control an optical mode of the light within the optical cavity 1204 based on the non-planar lateral phase profile Φ. As a result, an RHPM 102 may beneficially facilitate the generation of a highly narrowband output laser beam 1206 with a highly-controlled optical mode.

It is further contemplated herein that two or more RHPMs 102 within an optical cavity 1204 designed for operation with different wavelengths within a gain profile of the gain medium 1202 may provide an output laser beam 1206 having multiple narrowband spectral peaks. For example, as illustrated in FIG. 8, a single phase transformation device 100 may include two or more RHPMs 102 within a common volume 104 to simultaneously retroreflect multiple wavelengths of light via Bragg diffraction. As another example, though not explicitly shown, a laser system 1200 may include multiple phase transformation devices 100, each including one or more RHPMs 102.

Further, each RHPM 102 within the optical cavity 1204 may separately control the mode profile of light within the cavity at an associated reflected wavelength based on the associated non-planar lateral phase profile. In some embodiments, multiple RHPMs 102 reflecting different wavelengths may provide a common optical mode profile for the different wavelengths (e.g., a Gaussian profile). In some embodiments, multiple RHPMs 102 reflecting different wavelengths may provide different optical mode profiles for the different wavelengths.

The herein described subject matter sometimes illustrates different components contained within, or connected with, other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “connected” or “coupled” to each other to achieve the desired functionality, and any two components capable of being so associated can also be viewed as being “couplable” to each other to achieve the desired functionality. Specific examples of couplable include but are not limited to physically interactable and/or physically interacting components and/or wirelessly interactable and/or wirelessly interacting components and/or logically interactable and/or logically interacting components.

It is believed that the present disclosure and many of its attendant advantages will be understood by the foregoing description, and it will be apparent that various changes may be made in the form, construction, and arrangement of the components without departing from the disclosed subject matter or without sacrificing all of its material advantages. The form described is merely explanatory, and it is the intention of the following claims to encompass and include such changes. Furthermore, it is to be understood that the invention is defined by the appended claims.

What is claimed:

1. A device comprising:
a solid photosensitive material having a planar input facet; and
one or more reflective holographic phase masks (RHPMs) within a volume of the solid photosensitive material, wherein a particular one of the one or more RHPMs is formed as a periodic refractive index variation of the solid photosensitive material along a particular grating vector and further with a particular non-planar lateral phase profile in at least one plane perpendicular to the particular grating vector, wherein at least one of a period of the refractive index variation along the grating vector or an orientation of the grating vector for each of the one or more RHPMs are arranged to reflect via Bragg diffraction light incident on the input facet that satisfies a Bragg condition, wherein a phase distribution of the reflected light is modified by the non-planar lateral phase profiles of the one or more RHPMs.

2. The device of claim 1, wherein the one or more RHPMs comprise:
two or more RHPMs in an overlapping region of the volume of the solid photosensitive material.

3. The device of claim 2, wherein the non-planar lateral phase profiles of the two or more RHPMs are equal.

4. The device of claim 2, wherein the non-planar lateral phase profiles of at least two of the two or more RHPMs are different.

5. The device of claim 2, wherein the two or more RHPMs are arranged to retroreflect light having two or more different wavelengths incident on the input facet via Bragg diffraction.

6. The device of claim 2, wherein the two or more RHPMs are arranged to reflect light having two or more different incidence angles on the input facet with a common reflection angle relative to the input facet.

7. The device of claim 6, wherein the light having the two or more different incidence angles on the input facet have different wavelengths.

8. The device of claim 6, wherein the light having the two or more different incidence angles on the input facet have equal wavelengths.

9. The device of claim 2, wherein the two or more RHPMs are arranged to reflect light having two or more different wavelengths incident on the input facet at a common incidence angle along different reflection angles with respect to the input facet.

10. The device of claim 2, wherein the two or more RHPMs are arranged to reflect light with a common wavelength at different reflection angles with respect to the input facet.

11. The device of claim 1, wherein the grating vector of at least one of the one or more RHPMs is oriented normal to the input facet.

12. The device of claim 1, wherein the grating vector of at least one of the one or more RHPMs is oriented at a non-normal angle with respect to the input facet.

13. The device of claim 1, wherein the solid photosensitive material comprises photo-thermo-refractive (PTR) glass.

14. A system comprising:
a laser source configured to generate a coherent beam of light;
an interferometer comprising:
a beamsplitter to split the coherent beam into two arms;
a phase mask in one of the two arms providing a non-uniform phase distribution in at least one direction perpendicular to a propagation direction of the coherent beam in the associated one of the two arms;
one or more optical elements configured to combine the coherent beam from the two arms in a sample to generate an interference pattern within the sample, wherein the interference pattern corresponds to a periodic intensity variation along a grating vector and provides a non-planar lateral phase profile in at least one plane perpendicular to the grating vector, wherein at least one of a period of the intensity variation along the grating vector or an orientation of the grating vector for each of the one or more RHPMs are arranged to satisfy a Bragg condition associated with the reflection of light incident on a planar input facet of the sample back out of the input facet.

15. The system of claim 14, further comprising:
an oven to heat the sample after generation of the interference pattern in the sample.

16. A laser system comprising:
a gain medium configured to generate optical gain;
a cavity surrounding the gain medium configured to generate output laser light based on the optical gain by the gain medium, wherein the cavity includes a reflective phase mask comprising:
a solid photosensitive material having a planar input facet;
one or more reflective holographic phase masks (RHPMs) within a volume of the solid photosensitive material, wherein a particular one of the one or more RHPMs is formed as a periodic refractive index variation of the solid photosensitive material along a grating vector normal to the input facet and further with a particular non-planar lateral phase profile in at least one plane perpendicular to the grating vector, wherein a period of the refractive index variation along the grating vector for each of the one or more RHPMs is arranged to retroreflect via Bragg diffraction light of a particular wavelength, wherein a phase distribution of the retroreflected light is modified by the non-planar lateral phase profiles of the one or more RHPMs, wherein optical modes of the output laser light associated with the wavelengths retroreflected by the one or more RHPMs are determined by the non-planar lateral phase profiles of the associated RHPMs.

17. The laser system of claim 16, wherein the one or more RHPMs comprise:
two or more RHPMs in an overlapping region of the volume of the solid photosensitive material.

18. The laser system of claim 17, wherein the non-planar lateral phase profiles of the two or more RHPMs are equal.

19. The laser system of claim 17, wherein the non-planar lateral phase profiles of at least two of the two or more RHPMs are different.

20. The laser system of claim 17, wherein the solid photosensitive material comprises photo-thermo-refractive (PTR) glass.

21. A system comprising:
two or more transmitters configured to generate modulated light beams at two or more wavelengths;
a multiplexer configured to receive the modulated light beams and direct the modulated beams along a transmission pathway;
two or more detectors; and
a demultiplexer configured to receive the modulated light beams from the transmission pathway and direct the modulated light beams along separate paths to the two or more detectors;
one or more phase transformation devices comprising:
a solid photosensitive material having a planar input facet; and
two or more reflective holographic phase masks (RHPMs) within a volume of the solid photosensitive material, wherein a particular one of the two or more RHPMs is formed as a periodic refractive index variation of the solid photosensitive material along a particular grating vector and further with a particular non-planar lateral phase profile in at least one plane perpendicular to the particular grating vector, wherein at least one of a period of the refractive index variation along the grating vector or an orientation of the grating vector for each of the two or more RHPMs are arranged to reflect light incident on the input facet that satisfies a Bragg condition, wherein a phase distribution of the reflected light is modified by the non-planar lateral phase profiles of the associated one or more RHPMs;
wherein at least one of the one or more phase transformation devices is configured to operate as at least one of the multiplexer or the demultiplexer.

22. The system of claim 21, wherein at least one of the one or more phase transformation devices is configured to operate as the multiplexer, wherein the two or more RHPMs of the multiplexer are arranged to reflect the modulated beams along a common reflection angle relative to the input facet.

23. The system of claim 21, wherein at least one of the one or more phase transformation devices is configured to operate as the demultiplexer, wherein the two or more RHPMs of the multiplexer are arranged to reflect the modulated beams from the transmission pathway along different reflection angles relative to the input facet.
